(19) United States
(12) Patent Application Publication
(10) Pub. No.: US 2010/0149756 A1
(43) Pub. Date: Jun. 17, 2010

(54) HEAT SPREADER

(76) Inventors: David Rowcliffe, Los Osos, CA (US); William Joseph Yost, III, Brookline, MA (US)

Correspondence Address: BRYAN CAVE LLP, 211 NORTH BROADWAY, SUITE 3600, ST. LOUIS, MO, 63102-2750, US

(21) Appl. No.: 12/335,678

(22) Filed: Dec. 16, 2008

(51) Int. Cl. H05K 7/20; F28F 7/00; B23P 17/00

(52) U.S. Cl. 361/714; 165/185; 29/592.1

(57) ABSTRACT

The present invention relates to a package comprising a plate formed from a diamond-composite material and a frame and its use as a lid or cavity lid in electronic packaging applications.

### FIELD OF THE INVENTION

The present invention relates to a package comprising a plate formed from a diamond-composite material and a frame and its use as a lid or cavity lid in electronic packaging applications.

### BACKGROUND OF THE INVENTION

Unwanted heat generation is a problem which is encountered increasingly frequently in the electronics industry. This is particularly the case in semiconductor assemblies which are typically subject to temperature cycling during their operation.

Electronic assemblies are generally constructed from a number of components formed from different materials. Wherever there is a boundary in such an assembly between materials of different thermal expansion coefficients, there is the possibility that warpage and movement may occur resulting in mechanical or electrical failure of components or interfaces within the assembly.

For this reason, in order to improve thermal performance and reliability, it is common practice to include thermal management components in such assemblies. Thermal management components generally comprise heat sinks used with or without discrete heat spreaders. Heat spreaders are made of materials with high thermal conductivity (typically >170 Wm⁻¹K⁻¹.) and can greatly improve the overall efficiency of heat removal from a system.

In certain instances, the heat spreader material can be incorporated into semiconductor assemblies as a lid for a chip (also known as a “die”). Such lids are commonly referred to as “cavity lids”. Typical heat spreader materials are based on aluminium or copper (e.g. aluminium nitride, copper-tungsten, etc). Currently available semiconductor assemblies incorporating heat spreaders fall into two classes, specifically lidded and lidless assemblies. In both these cases heat is transferred from the surface of the silicon die into the heat spreader by conduction often through a so-called “thermal grease”. The heat is spread laterally by the heat spreader and subsequently to the heat sink where it is typically dissipated to the environment. In a lidded assembly, the lid covers the die of the semiconductor to provide mechanical strength and serve as a mechanism for transferring load forces present in the package to the substrate to which the semiconductor die is attached. In a lidless assembly, the forces applied above the die have to be carefully controlled as force transfer will occur through the die itself. In this regard, as a consequence of the mechanical strength imparted to the package, lidded packages are preferred. However, lidded assemblies have associated disadvantages. There is generally a poor match between the coefficient of thermal expansion (CTE) of the lid material and the CTE of the die and/or the substrate onto which the die is mounted. Hence the possibility that warpage and movement may occur resulting in mechanical or electrical failure of components or interfaces within the assembly is increased. Where the die is a silicon die, the CTE of the die material is typically about 2.6 ppmK⁻¹ at room temperature (that is, about 300 K).

Attempts have been made to overcome this problem. U.S. Pat. No. 6,637,506 describes a method of enhancing the thermal match between portions of a semiconductor assembly. The method involves the use of a heat spreader which comprises a centre portion and a perimeter portion where the perimeter portion is formed from a material having a lower CTE than the centre portion. The perimeter portion serves to restrict the expansion of the centre portion while providing a match with the CTE of the substrate and the die.

As described above, it is essential that the heat spreader is formed from a material which has a high thermal conductivity. Diamond is a material known to have a very high thermal conductivity and therefore lends itself to use in such applications.

The specifications for placing and joining a heat spreader component require that the dimensions and surface finish of the heat spreader are carefully controlled. As a consequence it is often costly and difficult to produce such components of the required high specifications. Machining diamond-based materials is particularly costly, and composite diamond materials are subject to edge chipping. Therefore, unique difficulties exist in incorporating a diamond-based heat spreader into semiconductor assemblies, which do not need to be considered when using alternative heat spreading materials.

An example of a diamond based material which has been used in this application is a diamond composite as described in U.S. Pat. No. 6,914,025. The composite material consists of three phases, specifically a diamond phase of diamond particles, a silicon carbide phase and an unreacted silicon or silicon alloy phase. The silicon carbide forms an interconnected skeletal material structure surrounding each individual diamond particle and silicon or silicon alloy fills the interstices of the silicon carbide skeleton. For this reason, such composite material is often referred to as “skeleton cemented diamond”. This composite material has a thermal conductivity of at least 400 Wm⁻¹K⁻¹ at room temperature (that is, about 300 K).

Methods for producing skeleton cemented diamond are described in U.S. Pat. No. 6,447,852, U.S. Pat. No. 6,709,747 and US 2004/247873. These methods generally involve the steps of forming a work piece of the desired dimensions from a blend of diamond particles, heating the workpiece under controlled temperature conditions to create a desired amount of graphite by graphitisation of diamond particles, infiltrating melted silicon or silicon alloy into the graphite body and reacting the molten silicon and graphite to form silicon carbide. By means of such a process it has been possible to produce skeleton cemented diamond material of many shapes and sizes.

While such material has proved to be an effective heat spreader, it is liable to imperfections, particularly at the edges where diamond particles may chip out of the silicon carbide matrix. Therefore it is expensive to manufacture composite diamond materials to the required high standards. As skeleton cemented diamond material having a high thermal conductivity generally comprises large diamond particles, this is particularly a problem where the thermal properties of the material are being exploited. The problem of edge chipping is increasingly a problem in industry where there is a drive towards automation of the manufacture of such assemblies. An example of a type of automated manufacturing system widely known in the art is referred to as a “Pick and Place” system. This system uses one or more optical sensors to locate the edges of a given component. Where the edges suffer from imperfections, this can cause inaccuracies in edge location and consequent problems in the assemblies being manufactured. Another problem with the use of skeleton cemented diamond in this application is that the toughness of the material is such that further damage may occur when picked up by robotic apparatus.

Monolithic cavity lids formed from skeleton cemented diamond material have been made commercially available from Skeleton Technologies, Inc. (Houston, Tex.). In addition to the edge chipping problems identified above, a further issue associated with such lids is that there is a large difference between the CTE of the skeleton cemented diamond material and the substrate to which it is attached in a semiconductor package. More specifically, skeleton cemented diamond material has a CTE of approximately 2 ppmK⁻¹ while substrate materials typically have a CTE in the range from about 12 to about 17 ppmK⁻¹.

In this regard, there is a need for an improved lid component for use in a semiconductor assembly which benefits from the high thermal conductivity associated with diamond but does not suffer from the aforementioned problems, specifically edge chipping and damage and warpage when incorporated into a semiconductor assembly as a consequence of poor CTE matching.

### SUMMARY OF THE INVENTION

The present invention provides a package comprising a plate of diamond material having first and second surfaces and a thickness, and at least one support member wherein said support member has a thickness, forms at least a portion of opposite edges of the plate and is formed from a material having a coefficient of thermal expansion at room temperature which is higher than that of the diamond material, a thermal conductivity at room temperature which is lower than that of the diamond material, a Young's modulus which is lower than that of the diamond material and which, in use, allows limited movement of the plate of diamond material in a direction parallel to the plane of the diamond plate but prevents movement of the plate of diamond material in a direction perpendicular to the plane of the diamond plate such that thermal contact with a surface of a component to which the plate is attached is maintained over at least 75% of the surface of the component.

In a further aspect, the present invention relates to the use of such packages as a cavity lid in an electronic assembly.

The present invention is hereinafter described by reference to the following figures and examples which are in no way intended to limit the scope of protection claimed.

### BRIEF DESCRIPTION OF THE DRAWINGS

FIG. 1 is a schematic representation of a cross-section of a first embodiment of a package of the present invention;

FIG. 2 is a plan view of a first embodiment of a package of the present invention;

FIG. 3 is a plan view of a second embodiment of a package of the present invention;

FIG. 4 is a schematic representation of a third embodiment of a package of the present invention;

FIG. 5 is a plan view of a fourth embodiment of a package of the present invention;

FIG. 6 is a plan view illustrating the production of an embodiment of a package of the present invention; and

FIG. 7 is a cross-section through an electronic assembly of the present invention.

### DETAILED DESCRIPTION OF THE INVENTION

As used herein, the term “room temperature” refers to a temperature of about 300 K.

The term “limited movement of the plate of diamond material” refers to the movement of the plate due to strain associated with thermal expansion.

In a yet further aspect, the present invention relates to an electronic assembly comprising a cavity lid as defined herein.

Hereinafter, the term “coefficient of thermal expansion” or “CTE” refers to the coefficient of thermal expansion of the material in question as measured at room temperature, that is, at about 300 K. The CTE of a material can be determined by dilatometry. This technique is well known and instruments for making such measurements are commercially available, for example, the QuickLine™-05 supplied by Anter Corporation, Pittsburgh, USA.

The package of the present invention benefits from the high thermal conductivity associated with diamond material. In addition, by virtue of the at least one support member, the package has at least two clearly defined edges making possible the use of a robotic “Pick and Place” system for installing the package. The problem of edge chipping is thus alleviated. Furthermore, by use of a support material which has the properties as defined above, in use, there is an improved match between the coefficient of thermal expansion of the support member and the substrate with which it will be in thermal contact. Advantageously, this minimises overall stress levels within the electronic assembly.

In addition, advantageously, the extent of the movement that needs to be accommodated by the package is reduced by the invention. The diamond material has a low thermal expansion coefficient and, because of its high thermal conductivity and connection to a heat sink, its temperature will not rise significantly above that of the ambient, thereby minimising the extent of any lateral movement. In one embodiment, the diamond material is skeleton cemented diamond material. This has the added advantage in that the package of the invention can be used to remove heat from dies of larger area than is possible with heat spreader materials of lower thermal conductivity and/or higher coefficient of thermal expansion.

The package for use in the present invention comprises a plate of diamond material. In use, the first and/or second surfaces of the plate of diamond material can be contacted with at least one further component. By use of a diamond material, advantageously high thermal conductivities are possible.

The term “diamond” includes, but is not limited to, diamond which has been made by a chemical vapour deposition (CVD) process, preferably a microwave plasma CVD process, diamond made by a high temperature-high pressure process and natural type Ia, type IIa and type IIb diamond. The diamond may be polycrystalline or single crystal diamond. Furthermore, the diamond material may be a diamond composite material.

The diamond material can be a diamond composite material. Examples of suitable diamond composite materials include diamond-silver composite, commercially available from Plansee SE, Reutte, Austria (www.plansee.com), diamond-copper composite commercially available from Sumitomo Electric, USA (www.sumitomoelectricusa.com), and diamond-silicon composite, commercially available from Harris International, USA (www.harrisinternational.com). In another embodiment, the diamond composite material is a diamond-silicon composite comprising diamond and silicon, and/or the diamond-silicon composite comprises diamond particles, silicon carbide and silicon or silicon alloy, commonly referred to as skeleton cemented diamond as described above. Skeleton cemented diamond has a coefficient of thermal expansion of approximately 1.8 to 2.3 ppmK⁻¹ measured at room temperature, a thermal conductivity of approximately 230 to 800 Wm⁻¹K⁻¹ measured at room temperature and a room temperature Young's modulus of approximately 570 to 740 Gpa. As will be appreciated by the person skilled in the art, the exact values will depend upon the specific composition of the material, and this can be used to tailor the material precisely to the application.

Optionally, the plate of diamond material may be metallised over at least a part of one or both of its surfaces in order to, for example, increase thermal contact with or facilitate joining to a component with which it will be contacted in use.

The package of the present invention comprises at least one support member. Inclusion of the support member provides two clear advantages. First, it avoids the problems with edge chipping commonly associated with diamond materials, in particular diamond composite materials.

Diamond materials, in particular diamond composite materials are prone to edge chipping and edge damage. Taking the example of skeleton cemented diamond, at an edge or corner of the plate, the extent and hence the strength of attachment of a particular diamond particle to the matrix is reduced as compared to across the face of the plate. The final finishing operation used to obtain the required flatness, roughness and parallelism is typically an abrasive grinding process, often using a diamond-containing grinding wheel. During the grinding process, diamond grains at the edge can be pulled out leaving chips in the edges. Where the composition of the skeleton cemented diamond is optimised for use in applications where maximising the thermal conductivity is advantageous, the diamond particles tend to be large compared with materials optimised for mechanical applications. It will be understood by the skilled person that the size of the chip is determined by the size of the diamond particles. As a consequence the edge chips resulting from final abrasive processing tend to be larger in materials optimised for thermal applications as opposed to mechanical applications. In addition the abrasive processing results in the slight preferential abrasion of the softer silicon carbide and silicon phases, particularly at and adjacent to the edges of the plate. This makes the edges of the plate more susceptible to damage during post-processing handling.

In the package of the present invention, the support member forms at least a portion of opposite edges of the plate. By surrounding the edges of the plate of diamond material, any pre-existing edge chips are hidden. In addition, by protecting at least a portion of the edges and/or corners of the plate of diamond material, the support member prevents further damage or chipping from occurring.

Second, by appropriate selection of the material from which the support member is formed, thermal stresses which arise at interfaces between components having different CTEs are minimised.

The package can include a single support member, and can be in the form of a continuous frame.

The thickness of the at least one support member defines the overall thickness of the package. The at least one support member can have a thickness of greater than or equal to the thickness of the plate. In another embodiment, the at least one support member has a thickness which is greater than the thickness of the plate such that a cavity lid is formed. When contacted with a die in an electronic assembly, the thickness of the support member can be approximately equal to the combined thickness of the plate of diamond material and the die. Where the at least one support member has a thickness of greater than the plate, in addition to supporting the plate and providing defined edges, it can also support any component with which the plate will be contacted in use.

In use, the support member will be in thermal contact with both the diamond material which forms the plate and the substrate of the electronic assembly into which it is incorporated. As described above, during manufacture and use, the electronic assembly will undergo various thermal cycles and thermal stresses arise where materials having different coefficients of thermal expansion and elastic moduli are attached together. There are thus two interfaces where a mismatch in coefficient of thermal expansion is potentially problematic. In general, the larger the difference in coefficients of thermal expansion, the greater the stress that is generated.

The present inventors have found that by matching or reducing the difference between the CTEs of the material from which the support member is formed and the substrate, an improvement in performance is observed. In this regard, the present inventors have found that thermal stresses generated at the interface between the support member and substrate with which it is contacted in use are more detrimental to performance, in that they can cause warpage of the entire package, than those generated at the interface between the support member and the plate of diamond material as the latter thermal stresses and consequent strains can be compensated for by forming the support member in an appropriate manner.

Therefore, rather than using a support material which has the same or a similar CTE to the diamond material which forms the plate, the present invention overcomes the problem by selecting a material which has a CTE which is greater than that of the diamond material which forms the plate and closer in value to the CTE of the substrate of the semiconductor assembly onto which the die is attached. The CTE of the support member can be less than that of substrate materials used in the production of semiconductor assemblies. In this regard, the support member can have a CTE which is intermediate between that of the diamond material and the substrate with which the support member will be contacted in use. In another embodiment, the CTE of the support member material is similar to the CTE of the substrate with which the support member will be contacted in use.

This ensures that, in use, thermal stresses between the support material and substrate of a semiconductor assembly are minimised. While thermal stresses between the support member and the diamond plate are not eliminated, the material from which the support member is formed is selected such that the support member has a structural compliance such that any warping as a consequence of these stresses is prevented.

The support member can be formed from a material which has a CTE in the range from about 4 ppmK⁻¹ to about 18 ppmK⁻¹, from about 5 ppmK⁻¹ to about 15 ppmK⁻¹, and/or from about 5 ppmK⁻¹ to about 12 ppmK⁻¹.

In use, the support member ensures that thermal contact is maintained between the first surface of the plate of diamond material and a surface of a component to which it is attached. Often this component will be a die. Thermal contact should be maintained over at least about 75%, at least about 80%, at least about 85%, and/or at least about 90% of the area of the surface of the component with which the first surface of the plate of diamond material is contacted. More specifically, the support member allows movement of the plate in a direction parallel to the plane of the diamond plate while preventing movement of the diamond plate in a direction perpendicular to the plane of the diamond plate. In this way, the support member provides a rigid frame which allows a certain degree of movement of the diamond plate in a lateral direction but not in a vertical direction, specifically a direction perpendicular to the plane of the diamond plate. As described above, this ensures that thermal contact is maintained and, as a consequence, an improvement in the removal of heat from the component is observed.

The at least one support member may take many different geometries and the specific dimensions depend on the operational needs of the assembly into which the package is to be incorporated. The optimum dimensions of the heat spreader as viewed from a thermal management perspective may, in many cases, be less than those required for mechanical reasons.

For example, the package may comprise a single continuous support member as described above. Alternatively, the package may comprise two support members positioned at diametrically opposed corners of the plate. In a further alternative arrangement, the package may comprise four support members positioned at each of the corners of the plate. Such non-continuous arrangements are advantageous in that they minimise the interfaces between materials with different thermal expansion coefficients and therefore minimise the generation of stress.

The support member is formed from a material which has a Young's modulus which is less than that of the diamond material. The material from which the support member is formed can have a Young's modulus of less than about 300 Gpa, preferably less than about 250 Gpa, preferably less than about 200 Gpa. This is advantageous as it ensures that the elastic properties of the material are appropriate to maintain thermal contact with the component to which the diamond plate will be attached in use.

The support member is formed from a material which has a thermal conductivity lower than that of the diamond material. This is advantageous as it ensures that heat dissipation through the heat spreader to the heat sink is maximised and the amount of heat that flows to the substrate via the support member is reduced. This prevents build up of heat elsewhere in the assembly into which the package is to be incorporated.

The support member can have a thermal conductivity of less than about 400 Wm⁻¹K⁻¹, less than about 300 Wm⁻¹K⁻¹, and/or less than about 200 Wm⁻¹K⁻¹, preferably less than about 150 Wm⁻¹K⁻¹.

Thermal conductivity values for most materials are readily available in the literature. Thermal conductivity is typically measured by Searle's bar method in which a temperature gradient is set up on a bar of known cross section using a known heat input and the temperature is measured at several points along the bar.

Examples of suitable materials include metals, ceramics such as alumina, glasses including fibre reinforced glasses and plastics. Preferably the at least one support member is formed from a metal as metals are easier to handle and process during manufacture and have a high mechanical robustness. Where the support member is formed from a metal, it may be a pure metal or an alloy of two or more metals. Suitable metals include titanium and its alloys, aluminium and it alloys, copper and its alloys, nickel and its alloys, molybdenum and stainless steels.

Advantageously, the support member may be formed from Kovar® which is commercially available from a number of sources. Kovar® is an alloy of nickel, iron and cobalt and has a coefficient of thermal expansion at room temperature of approximately 5 ppmK⁻¹, a room temperature thermal conductivity of about 17.3 Wm⁻¹ K⁻¹ and a Young's modulus of approximately 140 Gpa. Kovar® is suitable for use as a support member in an apparatus according to the present invention, as it can be formed into a structure that prevents movement of the diamond plate in a direction perpendicular to the plane of the diamond plate whilst accommodating small amounts of movement due to thermal expansion parallel to the plane of the diamond plate.

The support member is designed such that, in use, any component of thermal expansion in a direction parallel to the major plane of the plate of diamond material does not result in a loss of thermal contact between the plate of diamond material and the surface of the component with which it is contacted. There are numerous ways in which this can be achieved; essentially they require introducing a “structurally compliant” element into the structure. This “structurally compliant” element might, for example, be an adhesive layer between the plate of diamond material and the support member or part of the support member comprising a concertina structure so that lateral stresses are not transformed into vertical stresses and vice-versa. The skilled person will be aware of alternative ways by which this can be achieved.

In the event that the at least one support member is required to exhibit other properties such as, for example, being electrically insulating and resistant to corrosion, materials such as ceramics, glass ceramics, plastics and fibre-reinforced plastics or polymers may be preferred.

Advantageously, the at least one support member is capable of being accurately located and securely gripped by a robotic assembly. In particular it is preferably free of edge imperfections larger than about 0.5 mm in any dimension, free of edge imperfections larger than about 0.2 mm in any dimension, free of edge imperfections larger than about 0.1 mm in any dimension, free of edge imperfections larger than about 0.05 mm in any dimension, free of edge imperfections larger than about 0.02 mm in any dimension, free of edge imperfections larger than about 0.01 mm in any dimension, and/or free of edge imperfections.

The term “edge imperfections” as used herein refers to features along or immediately adjacent to the edge of the diamond plate, including chip-outs, cracks, pulled out grains, surface lumps and other similar features. Such features may be observed using a stereo (“binocular”) microscope with a magnification in the range ×10 to ×50. An example of a suitable microscope is a Zeiss DV4 (Carl Zeiss Inc, Thornwood, N.Y., USA).

The plate of diamond material is attached to the at least one support member by an adhesive or mechanically, for example with clips, face plates, springs, screws or dowels etc.

Alternatively, the at least one support member may be formed from a plastics material which is moulded around the plate of diamond material by moulding, extrusion or any other technique known in the art.

The dimensions of the plate of diamond material are selected depending on the electronic assembly into which the package is to be incorporated. To maximise dissipation of heat, the plate can have a surface area which is larger than the surface area of the die to which it is attached in use. In one embodiment, the plate has a surface area which is at least about twice that of the die to which it is attached in use.

To maximise the dissipation of heat, it is preferred that the first and second surfaces of the plate of diamond material are flat. The flatness, as described by the deviation from flat, can be better than about 50 μm/mm, better than about 25 μm/mm, better than about 10 μm/mm, and/or better than about 5 μm/mm. Flatness can be determined by any suitable means known in the art. Examples of suitable means are by use of a micrometer or similar measuring instrument or by reflection interferometry, typically at a wavelength of 633 nm. Preferably the plate of diamond material has a surface roughness Rₐ in the range from about 1 nm to about 500 nm, from about 5 nm to about 100 nm, and/or from about 10 nm to about 50 nm. Surface roughness is typically measured using a stylus profilometer, but other means known in the art such as non-contact optical profilometry may also be used.

The first and second surfaces of the plate of diamond material can be parallel to each other. Preferably the parallelism, as described by the deviation from parallel, is better than about 50 μm/mm, better than about 25 μm/mm, better than about 10 μm/mm, and/or better than about 5 μm/mm. Parallelism can be determined by use of a micrometer or similar measuring instrument.

The present invention further provides an electronic assembly comprising:

a substrate;

a die; and

a cavity lid in thermal contact with the die and the lid, wherein the cavity lid comprises a plate of diamond material having first and second surfaces and a thickness, and at least one support member wherein said support member has a thickness, forms at least a portion of opposite edges of the plate and is formed from a material having a coefficient of thermal expansion at room temperature which is higher than that of the diamond material, a thermal conductivity at room temperature which is lower than that of the diamond material, a Young's modulus at room temperature which is lower than that of the diamond material and which, in use, allows movement of the plate of diamond material in a direction parallel to the plane of the diamond plate but prevents movement of the plate of diamond material in a direction perpendicular to the plane of the diamond plate wherein the first surface of the plate is in thermal contact with a surface of the die, the support member is in thermal contact with the plate of diamond material and the substrate and, in use, the thermal contact between the first surface of the plate of diamond material and die is maintained over at least 75% of the surface of the die.

The electronic assembly of the present invention is capable of being accurately located and securely gripped by a robotic assembly. In particular it is preferably free of edge imperfections larger than about 0.5 mm in any dimension, free of edge imperfections larger than about 0.2 mm in any dimension, free of edge imperfections larger than about 0.1 mm in any dimension, free of edge imperfections larger than about 0.05 mm in any dimension, free of edge imperfections larger than about 0.02 mm in any dimension, free of edge imperfections larger than about 0.01 mm in any dimension, and/or free of edge imperfections.

The electronic assembly can also include a heat sink in thermal contact with the second surface of the plate of diamond material. This is advantageous in that it further improves the efficiency with which heat is removed from the assembly.

Thermal contact between the different components in the assembly may be achieved by use of a thermal grease or alternatively by mechanical means. Suitable thermal greases include CircuitWorks® Heat Sink Grease supplied by ITW Chemtronics (Kennesaw, Ga.).

Where the thickness of the support member is greater than the thickness of the plate of diamond material, preferably the at least one support member is adhered to the substrate in order to improve the stability of the assembly. Adhesion may be by use of an adhesive or by mechanical means. A suitable adhesive is epoxy resin such as Araldite® supplied by Huntsman Advanced Materials (Everberg, Belgium).

The electronic assembly of the present invention may be hermetically sealed to produce a product which complies with MIL-STD-883.

Advantageously, the cavity lid is formed from a package of the present invention as defined above.

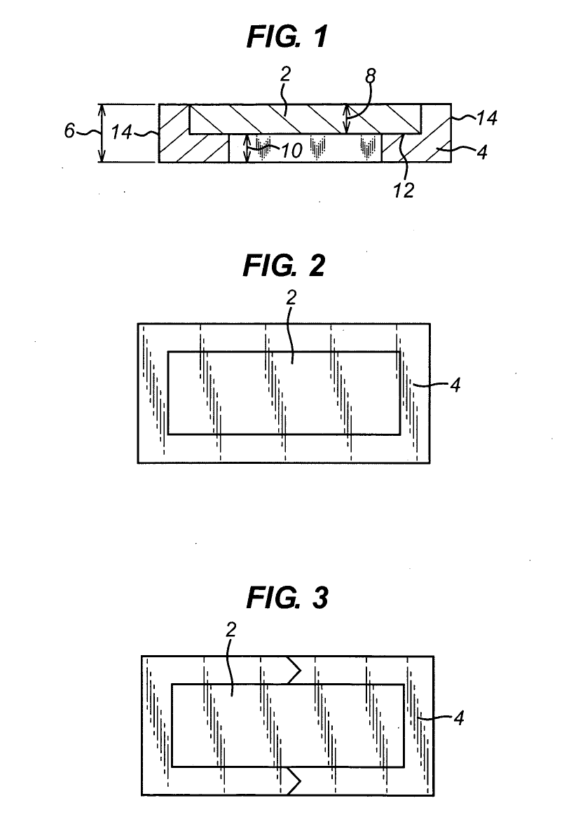

FIG. 1 shows a cross-sectional view of a first embodiment of a package of the present invention. The package comprises a flat plate of diamond based material (2) contained within a continuous frame (4). The thickness of the frame (6) is greater than the thickness of the flat plate (8) such that a cavity depth (10) is defined. The flat plate rests in an inset (12) in the frame. The thickness of the inset is equal to the thickness of the flat plate such that the plate lies flush with the top surface of the frame. The plate can be mechanically fixed into the frame or may be attached by means of an adhesive. The outer edges of the frame (14) provide a well-defined reference point for package by means of a robotic “Pick and Place” system.

FIG. 2 is a plan view of the first embodiment described by reference to FIG. 1. It is clear that in this embodiment, the at least one support member is in the form of a continuous frame. As illustrated in FIG. 3, the continuous frame may be formed as a single part or may be formed from a plurality of parts which have been connected together.

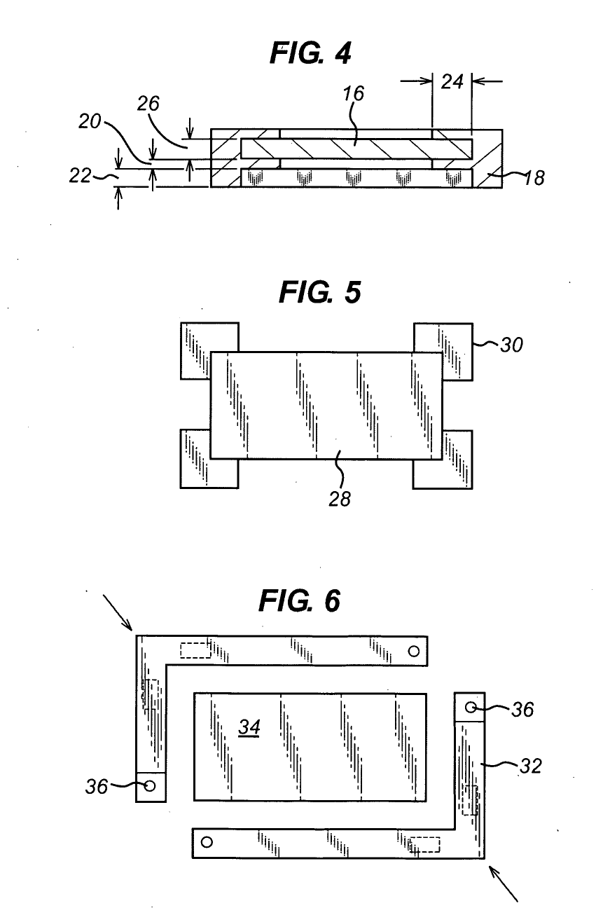

FIG. 4 a cross-sectional view of a third embodiment of a package of the present invention. The package comprises a flat plate of diamond based material (16) contained within a continuous frame (18). The frame has a notch which has a height (26) and a depth (24) designed so as to accommodate the plate of diamond material. The desired cavity depth is achieved by selecting appropriate thicknesses (20) and (22).

FIG. 5 is a plan view of a fourth embodiment of an package of the present invention which comprises a plate of diamond material (28) and four support members (30) positioned at each corner of the plate of diamond material.

FIG. 6 is a plan view illustrating the production of an embodiment of a package according to the present invention. Two L-shaped support members (32) are positioned at diametrically opposed corners of the plate of diamond material (34). In forming the package according to the present invention, the two support members are pushed together such that the screw holes (36) are aligned, thus forming a continuous frame surrounding the plate of diamond material.

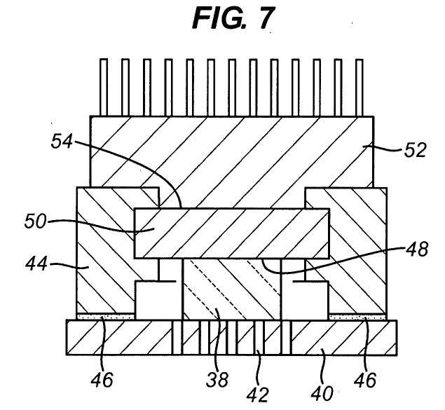

FIG. 7 is a cross-section through an electronic assembly according to the present invention. The assembly comprises a substrate (40) having metallic LGA (land grid array) connections (42), a silicon chip/die (38), a package according to the present invention comprising a support member (44) and a plate of diamond material (50) adhered (46) to the substrate; and a heat sink (52). The support member is in thermal contact with the substrate. The first surface (48) of the plate of diamond material is in thermal contact with the silicon chip and the second surface (54) of the plate of diamond material is in thermal contact with the heat sink.

### EXAMPLES

A plate of skeleton cemented diamond material (ScD C60® from Skeleton Technologies Inc., Houston) having dimensions of 45 mm×45 mm×4 mm are prepared. The plate of skeleton cemented diamond material has a coefficient of thermal expansion of approximately 1.8 ppmK⁻¹, a Young's modulus of approximately 740 Gpa and a thermal conductivity of approximately 600 Wm⁻¹K⁻¹.

An area of 25×25 mm² in the centre of the plate of skeleton cemented diamond material is metallised with Ti/Pt/Au by sputtering to thickness of about 2 nm/50 nm/5 μm.

Two “L-shaped” support members comprised of widely available oxygen-free high conductivity (“OFHC”) grade copper and threaded with screw holes for connection to each other and corner post pegs for package onto a substrate, are used. Copper has a coefficient of thermal expansion (at room temperature) of approximately 17 ppmK⁻¹, a Young's modulus of approximately 120 Gpa and a thermal conductivity of less than 400 Wm⁻¹K⁻¹. Each support member has a notch with a depth (24) of 2.5 mm for insertion of the plate of diamond material (16). The notch has a height (26) of approximately 4 mm. Fill holes are included on the side wall of each support member.

The package according to the present invention is prepared as shown in FIG. 5. More specifically, the plate of metallised skeleton cemented diamond material (34) is inserted into the slot of one of the L shaped support members (32). The plate of skeleton cemented diamond material is then guided into the slot of the other L shaped support member. The two support members are then pushed together such that the screw holes (36) were aligned and the support members surrounded all four sides of the plate of diamond material. The package of the present invention is formed by screwing the two support members to firmly fix the plate of diamond material within the frame. An epoxy resin with a curing temperature in the range from 100° C. and 150° C. is then injected into the fill holes to fill any gaps in the notch. The package is then thermally cured.

An electronic assembly according to the present invention and as illustrated in FIG. 7 is then prepared. A silicon chip (38) is mounted on to a ceramic substrate (40) (Al₂O₃) which has metallic LGA connections (42). The support members (44) of the package of the present invention are attached to the substrate by soldering with a soft (e.g. indium-based) solder (46) such that the first surface (48) of the plate of diamond material (50) is in thermal contact with the surface of the die not in contact with the substrate. A heat sink (52) is attached to the second surface (54) of the plate of diamond material. The base of the heat sink is designed so as to fit into the recess formed by the top of the frame mount. The heat sink is mounted on the second surface of the plate of diamond material using a thermal grease.

The properties of the support member are such that, in use, where thermal stresses are generated due to a mismatch in CTEs, the plate of diamond material can move in a direction parallel to the plane of the plate but not in a vertical direction relative to the substrate. Thus thermal contact between the first surface of the plate of diamond material and the die is maintained over more than 75% of the surface of the die. Advantageously, therefore the package of the present invention is particularly efficient at removing heat from the electronic assembly.

What is claimed is:

1. A package comprising a plate of diamond material having first and second surfaces and a thickness, and at least one support member wherein said support member has a thickness, forms at least a portion of opposite edges of the plate and is formed from a material having a coefficient of thermal expansion at room temperature which is higher than that of the diamond material, a thermal conductivity at room temperature which is lower than that of the diamond material, a Young's modulus at room temperature which is lower than that of the diamond material and which, in use, allows movement of the plate of diamond material in a direction parallel to the plane of the diamond plate but prevents movement of the plate of diamond material in a direction perpendicular to the plane of the diamond plate such that thermal contact with a surface of a component to which the plate is attached is maintained over at least about 75% of the surface of the component.

2. A package according to claim 1 wherein the at least one support member is capable of being accurately located and securely gripped by a robotic assembly.

3. A package according to claim 2 wherein the support member is free of edge perfections larger than about 0.5 mm in any dimension.

4. A package according to claim 1 wherein the package comprises a single support member.

5. A package according to claim 1 wherein the package comprises two support members positioned at diametrically opposed corners of the plate.

6. A package according to claim 1 wherein the package comprises four support members positioned at each of the corners of the plate.

7. A package according to claim 4 wherein the support member is a continuous frame having an opening therethrough into which the plate is received.

8. A package according to claim 7 wherein the plate is contained entirely within the opening of the frame.

9. A package according to claim 7 wherein the frame includes a lip around an inner perimeter thereof which defines a first surface which is contacted with the first surface of the plate.

10. A package according to claim 1 wherein the at least one support member has a thickness of greater than or equal to the thickness of the plate.

11. A package according to claim 1 wherein the diamond material has a coefficient of thermal expansion in the range from about 1 ppmK⁻¹ to about 5 ppmK⁻¹.

12. A package according to claim 1 wherein the diamond material is a diamond composite.

13. A package according to claim 12 wherein the diamond composite is selected from the group consisting of diamond-silver, diamond-copper and diamond-silicon composites.

14. A package according to claim 12 wherein the plate is made from composite diamond material comprising a mixture of diamond particles, silicon carbide and silicon or a silicon alloy.

15. A package according to claim 1 wherein the plate is made from polycrystalline diamond.

16. A package according to claim 1 wherein the plate is made from chemical vapour deposition (CVD) diamond.

17. A package according to claim 1 wherein the plate is flat.

18. A package according to claim 1 wherein the plate is adhesively bonded to the support member.

19. A package according to claim 1 wherein the plate is mechanically attached to the at least one support member.

20. A package according to any claim 1 wherein the at least one support member is formed from a material having a coefficient of thermal expansion in the range from about 6 ppmK⁻¹ to about 18 ppmK⁻¹.

21. A package according to claim 1 wherein the support member is made from a metal.

22. A cavity lid comprising a package as defined in claim 1

23. A method of manufacturing an electronic apparatus wherein a package as defined in claim 1 is incorporated into an electronic apparatus using a robotic “Pick and Place” system.

24. An electronic assembly comprising:
a substrate;
a die; and
a cavity lid in thermal contact with the die and the lid, wherein the cavity lid comprises a plate of diamond material having first and second surfaces and a thickness, and at least one support member wherein said support member has a thickness, forms at least a portion of opposite edges of the plate and is formed from a material having a coefficient of thermal expansion at room temperature which is higher than that of the diamond material, a thermal conductivity at room temperature which is lower than that of the diamond material, a Young's modulus at room temperature which is lower than that of the diamond material and which, in use, allows movement of the plate of diamond material in a direction parallel to the plane of the diamond plate but prevents movement of the plate of diamond material in a direction perpendicular to the plane of the diamond plate wherein the first surface of the plate is in thermal contact with the die, the support member is in thermal contact with the plate of diamond material and the substrate and, in use, thermal contact between the plate of diamond material and a surface of the die is maintained over at least about 75% of the surface of the die.

25. The electronic assembly according to claim 24, wherein the support member is capable of being accurately located and securely gripped by a robotic assembly.

26. The electronic assembly according to claim 24, wherein the at least one support member is formed from a material having a coefficient of thermal expansion which is lower than the coefficient of thermal expansion of the substrate.

27. The electronic assembly according to claim 24, further comprising a heat sink, wherein the second surface of the flat plate is in contact with the heat sink.

28. The electronic assembly according to claim 24, wherein the heat spreader is adhesively attached to the die.

29. The electronic assembly according to claim 24, wherein the at least one support member has a thickness of greater than or equal to the thickness of the plate of diamond material.

30. The electronic assembly according to claim 24, wherein the plate of diamond material is formed from a diamond composite.

31. The electronic assembly according to claim 30, wherein the diamond composite is skeleton cemented diamond.

32. The electronic assembly according to claims 24, wherein the support member is formed from a metal having a coefficient of thermal expansion at room temperature in the range from about 6 ppmK⁻¹ to about 18 ppmK⁻¹, and a Young's modulus at room temperature of less than about 300 GPa and a thermal conductivity at room temperature of less than about 400 Wm⁻¹K⁻¹.
